(19) United States
(12) Patent Application Publication
(10) Pub. No.: US 2009/0135897 A1
(43) Pub. Date: May 28, 2009

(54) SEMICONDUCTOR INTEGRATED CIRCUIT AND ELECTRONIC DEVICE

(76) Inventors: Yasuhito Soma, Osaka (JP); Shinetsu Kato, Osaka (JP); Naotake Kitahira, Osaka (JP)

Correspondence Address: WENDEROTH, LIND & PONACK L.L.P., 1030 15th Street, N.W., Suite 400 East, Washington, DC, 20005-1503, US

(21) Appl. No.: 12/159,746

(22) PCT Filed: Sep. 7, 2007
(86) PCT No.: PCT/JP2007/067479

§ 371 Date: Jun. 30, 2008

(30) Foreign Application Priority Data
Oct. 4, 2006 (JP) 2006-273240

(51) Int. Cl. H03K 7/08

(52) U.S. Cl. 375/238

(57) ABSTRACT

An electronic device (11) according to the present invention includes a semiconductor integrated circuit (16) on which a pulse conversion circuit (17) for converting an acoustic signal received by a radio receiver (13) into a pulse signal is integrated. The pulse conversion circuit (17) includes a clock generator (110) which generates plural clocks and selects word clocks (210,211) according to the reception frequency of the radio receiver (13), an FSC (111) which performs sampling frequency conversion so as to make a sample sequence of an A/D converted acoustic signal have the same frequency as that of the word clock (210), a noise shaper (112) for performing noise shaping to the sample sequence outputted from the FSC (111) using the word clock (211), and a PWM modulator (113) for generating a pulse signal from the output of the noise shaper (112) using the word clock (211). Therefore, it is possible to avoid radio reception interference which may caused by the pulse signal when driving a speaker with the pulse signal.

### TECHNICAL FIELD

The present invention relates to a pulse conversion circuit for converting an input sample sequence having a predetermined sampling frequency into a pulse signal, and more particularly, to a pulse conversion circuit used for an audio digital amplifier. Further, the invention relates to a semiconductor integrated circuit having the pulse conversion circuit is integrated, and an electronic device having the semiconductor integrated circuit is mounted.

### BACKGROUND ART

In recent years, a digital amplifier which converts an acoustic signal into a pulse signal by a pulse conversion circuit and amplifies this pulse signal to drive a speaker is widely spreading. Although the digital amplifier has an advantage that its energy efficiency is higher than that of a conventional analog amplifier, it has a disadvantage that since the digital amplifier drives the speaker with a high-voltage and large-current pulse signal, radio reception interference occurs due to the pulse signal when it is integrated with or disposed close to a radio receiver.

Conventionally, there has been proposed an analog type pulse conversion circuit which can avoid such radio reception interference by switching a carrier frequency of a pulse signal according to a reception frequency of a radio receiver (for example, refer to Patent Document 1).

In recent years, however, digitization of the pulse conversion circuit has been demanded to facilitate integration onto a semiconductor integrated circuit. For this purpose, a technique for avoiding radio reception interference which may be caused by the pulse signal in the digital type pulse conversion circuit has been demanded. Conventionally, as a method for avoiding radio reception interference in the digital type pulse conversion circuit, there has been proposed a method of changing the frequency of the pulse signal to a fundamental frequency or half of the fundamental frequency according to a reception frequency of radio broadcasting without changing the carrier frequency of the pulse signal (for example, refer to Patent Document 2).

Patent Document 1: Japanese Published Patent Application No. Hei. 6-29757 (paragraph [0020], FIG. 1)

Patent Document 2: Japanese Published Patent Application No. 2003-332858 (paragraph [0054], FIGS. 2 and 5)

### DISCLOSURE OF THE INVENTION

### Problems to be Solved by the Invention

However, the conventional pulse conversion circuit has the following drawbacks.

Since the pulse conversion circuit disclosed in Patent Document 1 is an analog circuit, it is difficult to integrate the same onto a semiconductor integrated circuit.

Further, while the pulse conversion circuit disclosed in Patent Document 2 as a digital circuit can be easily integrated onto a semiconductor integrated circuit, since, in the pulse conversion circuit, the frequency of the pulse signal to be changed according to the radio reception frequency is restricted to the fundamental frequency or to the half thereof, radio reception interference due to even harmonics (double, quadruple, . . . ) of the fundamental frequency cannot be reduced.

Accordingly, the present invention has for its object to provide a digital system pulse conversion circuit which can reduce radio reception interference irrespective of the reception frequency, a semiconductor integrated circuit including the pulse conversion circuit, and an electronic device having the semiconductor integrated circuit.

### Measures to Solve the Problems

According to the present invention, there is provided a pulse conversion circuit included in an electronic device having a radio receiver which receives radio broadcasting and a controller which outputs an output sampling frequency change instruction corresponding to a reception frequency of the radio receiver, which pulse conversion circuit comprises: a clock generator for generating plural clock signals having different frequencies, and selecting a clock signal to be outputted among the plural clock signals in accordance with the output sampling frequency change instruction; a sampling frequency converter for sampling a first sample sequence that is obtained by sampling an acoustic signal received by the radio receiver with a first sampling frequency, using the frequency of the clock signal outputted from the clock generator, thereby converting it to a second sample sequence of a second sampling frequency; a noise shaper for receiving the second sample sequence as an input, and performing noise shaping to the second sample sequence with a third sampling frequency which is a multiple of the second sampling frequency; and a pulse modulator for modulating a signal outputted from the noise shaper into a pulse signal using the third sampling frequency.

Further, in the pulse conversion circuit according to the present invention, the pulse modulator includes a counter which, initialized by the clock signal of the third sampling frequency, counts the number of reference clocks, a first comparison circuit for comparing the output of the noise shaper with the output of the counter, and a second comparison circuit for comparing an inversion result of the output of the noise shaper with the output of the counter, and the comparison results obtained in the first and second comparison circuits being outputted as pulse signals.

Further, in the pulse conversion circuit according to the present invention, the clock generator includes a timing adjustment circuit which, while monitoring the phases of the plural clock signals, switches the output of the clock signal at a timing when the rising edges of the clock signal before the switching and the clock signal after the switching are aligned with each other, when selecting the clock signal to be outputted in accordance with the output sampling frequency change instruction.

Further, in the pulse conversion circuit according to the present invention, the sampling frequency converter includes plural frequency ratio detection circuits for detecting frequency ratios between the clock signal synchronized with the first sampling frequency and the clock signals outputted from the clock generator to output frequency ratio detection signals, respectively, a selector circuit for receiving the plural frequency ratio detection signals outputted from the plural frequency ratio detection circuits, and selecting a frequency ratio detection signal to be outputted in accordance with the output sampling frequency change instruction, an over-sampling filter for integer-multiplying the sampling frequency of the first sample sequence, an interpolation circuit for interpolating the sample sequence outputted from the over-sampling filter, using the frequency ratio detection signal outputted from the selection circuit, and a storage circuit for storing the sample sequence outputted from the interpolation circuit, and outputting the stored sample sequence as the second sample sequence with the period of the clock signal.

Further, in the pulse conversion circuit according to the present invention, each of the frequency ratio detection circuits measures the number of clocks of the clock signal synchronized with the first sampling frequency within one period of a clock signal which is obtained by frequency-dividing the inputted clock signal with a predetermined frequency division ratio, and obtains the sum of the continuous plural measurement results as a frequency ratio.

Further, in the pulse conversion circuit according to the present invention, an amplitude adjustment unit for adjusting the amplitude of the acoustic signal by varying the sample values in the first sample sequence is provided in the previous stage of the sampling frequency converter, and the amplitude adjustment unit varies the sample values in the first sample sequence in accordance with an amplitude adjustment instruction corresponding to the reception frequency of the radio receiver, which instruction is outputted from the controller.

Further, in the pulse conversion circuit according to the present invention, an amplitude adjustment unit for adjusting the amplitude of the acoustic signal by varying the sample values in the second sample sequence is provided in the subsequent stage of the sampling frequency converter, and the amplitude adjustment unit varies the sample values in the second sample sequence in accordance with an amplitude adjustment instruction corresponding to the reception frequency of the radio receiver, which instruction is outputted from the controller.

Further, in the pulse conversion circuit according to the present invention, the sampling frequency converter includes an over-sampling filter for integer-multiplying the sampling frequency of the first sample sequence, and the over-sampling filter having plural low-pass filters of different cutoff frequencies switches the low-pass filters that perform band-restrictions on the first sample sequence, according to a band setting instruction corresponding to the operation mode of the radio receiver, which instruction is outputted from the controller.

Further, according to the present invention, there is provided a semiconductor integrated circuit on which a pulse conversion circuit of an electronic device is integrated, the electronic device having a radio receiver for receiving radio broadcasting and a controller for outputting an output sampling frequency change instruction corresponding to a reception frequency of the radio receiver, wherein the pulse conversion circuit comprises: a clock generator for generating plural clock signals having different frequencies, and selecting a clock signal to be outputted, from among the plural clock signals in accordance with the output sampling frequency change instruction; a sampling frequency converter for sampling a first sample sequence that is obtained by sampling an acoustic signal received by the radio receiver with a first sampling frequency, using the frequency of the clock signal outputted from the clock generator, thereby converting it to a second sample sequence of a second sampling frequency; a noise shaper for receiving the second sample sequence as an input, and performing noise shaping to the second sample sequence with a third sampling frequency which is a multiple of the second sampling frequency; and a pulse modulator for modulating a signal outputted from the noise shaper into a pulse signal using the third sampling frequency.

Further, the semiconductor integrated circuit according to the present invention includes a clock generator for generating plural clocks having different frequencies, a selector for selecting one clock among the plural clocks generated by the clock generator in accordance with an operation clock switching instruction corresponding to the reception frequency of the radio receiver, which instruction is outputted from the controller, and a signal processing unit which is operated with the clock outputted from the selector as an operation clock.

Further, in the semiconductor integrated circuit according to the present invention, an amplitude adjustment unit for adjusting the amplitude of the acoustic signal by varying the sample values in the first sample sequence is provided in the previous stage of the sampling frequency converter in the pulse conversion circuit, and the amplitude adjustment unit varies the sample values in the first sample sequence in accordance with an amplitude adjustment instruction corresponding to the reception frequency of the radio receiver, which instruction is outputted from the controller.

Further, in the semiconductor integrated circuit according to the present invention, an amplitude adjustment unit for adjusting the amplitude of the acoustic signal by varying the sample values in the second sample sequence is provided in the subsequent stage of the sampling frequency converter in the pulse conversion circuit, and the amplitude adjustment unit varies the sample values in the second sample sequence in accordance with an amplitude adjustment instruction corresponding to the reception frequency of the radio receiver, which instruction is outputted from the controller.

Further, in the semiconductor integrated circuit according to the present invention, the sampling frequency converter in the pulse conversion circuit includes an over-sampling filter for integer-multiplying the sampling frequency of the first sample sequence, and the over-sampling filter having plural low-pass filters of different cutoff frequencies switches the low-pass filters that perform band-restrictions on the first sample sequence, in accordance with a band setting instruction corresponding to the operation mode of the radio receiver, which instruction is outputted from the controller.

Further, according to the present invention, there is provided an electronic device comprising: a radio receiver for receiving radio broadcasting; a controller for setting a reception frequency of the radio receiver, and outputting an output sampling frequency change instruction corresponding to the reception frequency of the radio receiver; a digital acoustic signal output unit for sampling an acoustic signal received by the radio receiver with a first sampling frequency to output the same as a first sample sequence; a clock generator for generating plural clock signals having different frequencies, and selecting a clock signal to be outputted among the plural clock signals in accordance with the output sampling frequency change instruction; a sampling frequency converter for sampling the first sample sequence that is outputted from the digital acoustic signal output unit, using the frequency of the clock signal outputted from the clock generator, thereby converting it to a second sample sequence of a second sampling frequency; a noise shaper for receiving the second sample sequence as an input, and performing noise shaping to the second sample sequence with a third sampling frequency that is a multiple of the second sampling frequency; and a pulse modulator for modulating the signal outputted from the noise shaper into a pulse signal using the third sampling frequency.

Further, in the electronic device according to the present invention, an amplitude adjustment unit for adjusting the amplitude of the acoustic signal by varying the sample values in the first sample sequence is provided in the previous stage of the sampling frequency converter, the controller outputs, to the amplitude adjustment unit, an amplitude adjustment instruction corresponding to the reception frequency of the radio receiver, and the amplitude adjustment unit varies the sample values in the first sample sequence in accordance with the amplitude adjustment instruction.

Further, in the electronic device according to the present invention, an amplitude adjustment unit for adjusting the amplitude of the acoustic signal by varying the sample values in the second sample sequence is provided in the subsequent stage of the sampling frequency converter, the controller outputs, to the amplitude adjustment unit, an amplitude adjustment instruction corresponding to the reception frequency of the radio receiver, and the amplitude adjustment unit varies the sample values in the second sample sequence in accordance with the amplitude adjustment instruction.

Further, in the electronic device according to the present invention, the sampling frequency converter includes an over-sampling filter for integer-multiplying the sampling frequency of the first sample sequence, the over-sampling filter has plural low-pass filters of different cutoff frequencies, the controller outputs a band setting instruction corresponding to the operation mode of the radio receiver to the over-sampling filter, and the over-sampling filter switches the low-pass filters that perform band-restrictions on the first sample sequence, in accordance with the band setting instruction.

### EFFECTS OF THE INVENTION

A pulse conversion circuit according to the present invention is a circuit provided in an electronic device having a radio receiver for receiving radio broadcasting, and it changes, when converting an acoustic signal received by the radio receiver into a pulse signal, the sampling frequency used for generation of the pulse signal according to the reception frequency of the radio receiver. Thereby, the carrier frequency of the pulse signal can be changed according to the reception frequency of the radio receiver, and consequently, radio reception interference which may be caused by the pulse signal can be avoided.

Further, a semiconductor integrated circuit according to the present invention includes a pulse conversion circuit which is provided in an electronic device having a radio receiver for receiving radio broadcasting, and it changes, when converting an acoustic signal received by the radio receiver into a pulse signal, the sampling frequency used for generation of the pulse signal according to the reception frequency of the radio receiver. Thereby, the carrier frequency of the pulse signal can be changed according to the reception frequency of the radio receiver, and consequently, radio reception interference which may be caused by the pulse signal can be avoided.

Further, an electronic device according to the present invention includes a semiconductor integrated circuit on which a radio receiver for receiving radio broadcasting and a pulse conversion circuit used with the radio receiver are integrated, and its changes, when converting an acoustic signal received by the radio receiver into a pulse signal, the sampling frequency used for generation of the pulse signal according to the reception frequency of the radio receiver. Thereby, the carrier frequency of the pulse signal can be changed according to the reception frequency of the radio receiver, and consequently, radio reception interference which may be caused by the pulse signal can be avoided.

Further, the pulse conversion circuit according to the present invention adjusts the amplitude of the acoustic signal received by the radio receiver when switching the carrier frequency of the pulse signal. Therefore, it is possible to suppress variations in the sound volume which may occur accompanying with the change in the carrier frequency.

Further, the pulse conversion circuit according to the present invention, being provided with plural low-pass filters of different cutoff frequencies, switches, when converting the sampling frequency of the acoustic signal, the low-pass filters that perform band-restrictions on the acoustic signal, according to the frequency band of the acoustic signal which varies for each operation mode of the radio receiver. Therefore, it is possible to remove noise components in the acoustic signal which vary for each operation mode of the radio receiver.

Further, the semiconductor integrated circuit according to the present invention is provided with a clock generator for generating plural clocks of different frequencies, and switches the operation clock for an internal signal processing circuit according to the reception frequency of the radio receiver. Therefore, it is possible to avoid radio reception interference which may be caused by the operation clock.

### BRIEF DESCRIPTION OF THE DRAWINGS

FIG. 1 is a block diagram illustrating a configuration example of an electronic device according to a first embodiment of the present invention.

FIG. 2 is a block diagram illustrating a configuration example of a clock generator 110 in the electronic device according to the first embodiment.

FIG. 3 is a diagram illustrating output signal waveforms from major parts of a pulse conversion circuit 17 in the electronic device according to the first embodiment.

FIG. 4 is a block diagram illustrating a configuration example of a PWM modulator 113 in the electronic device according to the first embodiment.

FIG. 5 is a diagram for explaining the operation of the PWM modulator 113 in the electronic device according to the first embodiment.

FIG. 6 is a diagram illustrating waveforms of pulse signals P and M outputted from the PWM modulator 113 in the electronic device according to the first embodiment, and a differential signal between the pulse signal P and the pulse signal M.

FIG. 7 is a block diagram illustrating a configuration example of an electronic device according to a second embodiment of the present invention.

FIG. 8 is a block diagram illustrating a configuration example of an FSC 111 of the electronic device according to the first or second embodiment.

FIG. 9 is a block diagram illustrating a configuration example of an electronic device according to a third embodiment of the present invention.

FIG. 10 is a block diagram illustrating a configuration example of an FSC 911 in the electronic device according to the third embodiment.

FIG. 11 is a block diagram illustrating a configuration example of an electronic device according to a fourth embodiment of the present invention.

FIG. 12 is a block diagram illustrating a configuration example of an over-sampling filter 1012 embedded in an FSC 1011 of an electronic device according to a fourth embodiment of the present invention.

### DESCRIPTION OF THE REFERENCE NUMERALS

11,71,91,101 . . . electronic device
12,72,92,102 . . . system controller
13,103 . . . radio receiver
14 . . . ADC
15 . . . serial/parallel converter
16,76,96,106 . . . semiconductor integrated circuit
17,77,97,107 . . . pulse conversion circuit
18 . . . amplifier
19 . . . LPF
20 . . . speaker
21 . . . sampling frequency change instruction
22,212 . . . master clock
23 . . . timing adjustment circuit
24 . . . 128 frequency divider
25 . . . 144 frequency divider
26 . . . 64 frequency divider
27 . . . 72 frequency divider
28,29,86,1105 . . . selector circuit
31 . . . amplitude adjustment instruction
41 . . . counter
42,44 . . . comparison circuit
43 . . . inversion circuit
81,91,1012 . . . over-sampling filter
82,92 . . . interpolation circuit
83,93 . . . storage circuit
84,85 . . . frequency ratio detection circuit
110 . . . clock generator
111,911,1011 . . . sampling frequency converter (FSC)
112 . . . noise shaper
113 . . . PWM modulator
210 . . . first word clock
211 . . . second word clock
213,214 . . . clock
215 . . . bit clock
714 . . . amplitude adjustment unit
912 . . . clock generator
913 . . . selector
1101 . . . 0 insertion circuit
1102,1103,1104 . . . LPF

### BEST MODE TO EXECUTE THE INVENTION

Hereinafter, a pulse conversion circuit, a semiconductor integrated circuit, and an electronic device according to the present invention will be described with reference to the drawings.

### Embodiment 1

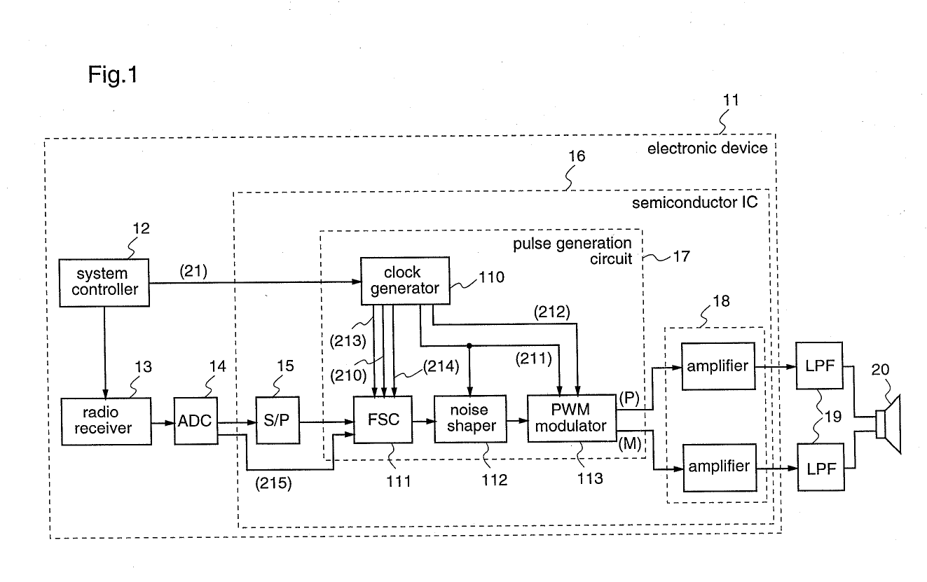

FIG. 1 is a block diagram illustrating configuration examples of an electronic device, a semiconductor integrated circuit included in the electronic device, and a pulse conversion circuit included in the semiconductor integrated circuit, according to a first embodiment of the present invention.

In FIG. 1, an electronic device 11 comprises a system controller 12 for controlling the whole electronic device, a radio receiver unit 13 for receiving radio broadcasting, and an analog-digital converter (ADC) 14 for analog-to-digital (A/D) converting an analog acoustic signal outputted from the radio receiver 13 to output a sample sequence. The output data from the ADC 14 are serial data comprising three lines of data, word clocks, and bit clocks. For example, an IIS format is adopted as a communication format of such acoustic data.

The system controller 12 sets a radio reception frequency of the radio receiver 13, and outputs, according to the radio reception frequency, an output sampling frequency change instruction 21 which instructs the pulse conversion circuit 17 to perform switching of a sampling frequency used when converting the sample sequence into a pulse signal. Thereby, the carrier frequency of the pulse signal outputted from the pulse conversion circuit 17 is separated from the reception frequency of the radio receiver 13.

The semiconductor integrated circuit 16 includes the pulse conversion circuit 17, a serial-parallel (S/P) converter 15 for converting the serial data outputted from the ADC 14 into parallel data to output the same to the pulse conversion circuit 17, and amplifiers 18 for amplifying pulse signals P and M outputted from the pulse conversion circuit 17. High-frequency components of the pulse signals P and M amplified by the amplifier 18 are removed by low pass filters (LPF) 19. A difference between the outputs from the two LPF 19 is detected in the speaker 20 to be outputted as audio.

The pulse conversion circuit 17 includes a clock generator 110 which generates plural clocks having different frequencies and selects clocks to be outputted (a first word clock 210 and a second word clock 211) in accordance with the output sampling frequency change instruction 21, a sampling frequency converter (FSC: Fs converter) 111 which receives the sample sequence outputted from the S/P 15 and converts the sampling frequency of the inputted sample sequence into the same frequency as that of the first word clock 210 outputted from the clock generator 110, a noise shaper 112 which performs noise shaping to the sample sequence outputted from the FSC 111 with the sampling frequency of the second word clock 211 outputted from the clock generator 110, and a PWM (Pulse Width Modulation) modulator 113 which modulates the signal outputted from the noise shaper 112 into pulse signals to output a positive-side pulse signal P and a negative-side pulse signal M. In this first embodiment, in order to enhance the noise shaping effect, the noise shaper 112 is operated with a sampling frequency which is a multiple (here, double) of the output sampling frequency of the FSC 111. Accordingly, the clock generator 110 sets the frequency of the second word clock 211 to be output to the noise shaper 112 and the PWM modulator 113, to a multiple (here, double) of the frequency of the first word clock 210.

Hereinafter, the specific circuit constructions of the respective parts of the pulse conversion circuit 17 will be described.

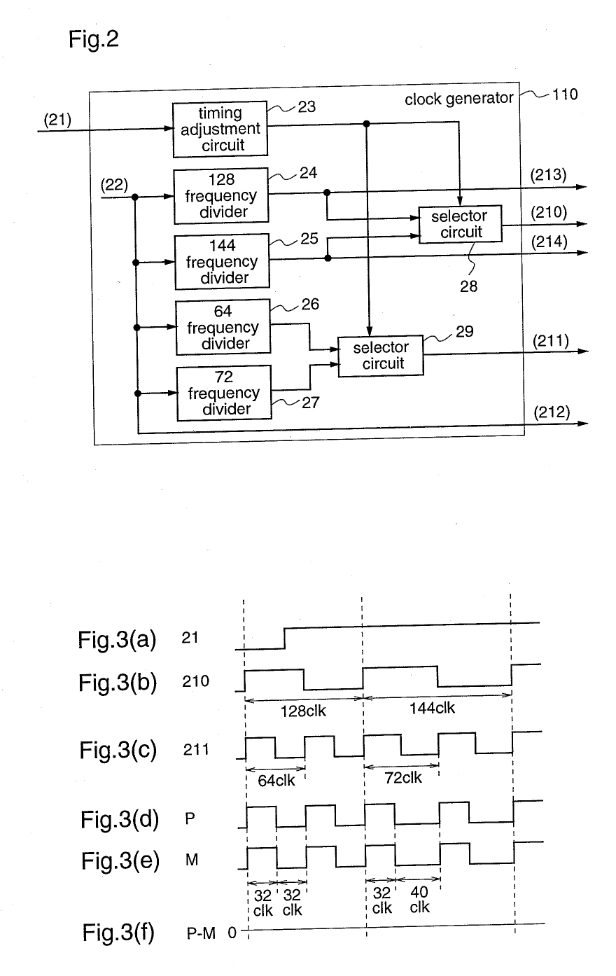

FIG. 2 is a block diagram illustrating a configuration example of the clock generator 110. The clock generator 110 generates plural clocks having different frequencies, and selects, among the plural clocks, the first word clock 210 to be output to the FSC 111 and the second word clock 211 to be output to the noise shaper 112 and the PWM modulator 113 in accordance with the output sampling frequency change instruction 21. Thereby, the frequencies of the first word clock 210 and the second word clock 211 are switched according to the frequency of the radio broadcasting signal received by the radio receiver 13.

In this first embodiment, in order to simplify the description, it is assumed that each of the first word clock 210 and the second word clock 211 is selected from two clocks. Therefore, the clock generator 110 includes four frequency dividers, i.e., a 128 frequency divider 24, a 144 frequency divider 25, a 64 frequency divider 26, and a 72 frequency divider 27 as shown in FIG. 2. These frequency dividers receive a master clock 22, and divide the clock with the respective frequency division ratios. The frequency division ratios of the respective frequency dividers are not restricted to 128, 144, 72, and 36, but optimum ratios are arbitrarily selected.

Further, since the noise shaper 112 is operated with the sampling frequency which is twice as high as the sampling frequency used in the FSC 111, the clock generator 110 has the 64 frequency divider 26 and the 72 frequency divider 27 whose frequency division ratios are half of those of the 128 frequency divider 24 and the 144 frequency divider 25 which generate the first word clock 210 to be output to the FSC 111, respectively. The second word clock 211 to be output to the noise shaper 112 and the PWM modulator 113 is generated by these 64 frequency divider 26 and 72 frequency divider 27. Further, when the noise shaper 112 is operated with the sampling frequency that is four times as high as the first word clock 210 outputted to the FSC 111, the clock generator 110 has a 32 frequency divider and a 36 frequency divider instead of the 64 frequency divider 26 and the 72 frequency divider 27, respectively.

Either of the clocks outputted from the 128 frequency divider 24 and the 144 frequency divider 25 is selected by the selection circuit 28 in accordance with the output sampling frequency change instruction 21 to be outputted as the first word clock 210. Further, either of the clocks outputted from the 64 frequency divider 26 and the 72 frequency divider 27 is selected by the selection circuit 29 in accordance with the output sampling frequency change instruction 21 to be outputted as the second word clock 211. To be specific, the output clock of the 128 frequency divider 24 and the output clock of the 64 frequency divider 26 are selected when the output sampling frequency change instruction 21 is L level, while the output clock of the 144 frequency divider 25 and the output clock of the 72 frequency divider 27 are selected when the output sampling frequency change instruction 21 is H level.

The timings when the first word clock 210 and the second word clock 211 thus generated are outputted from the selection circuits 28 and 29, respectively, are controlled by a timing adjustment circuit 23 in accordance with the output sampling frequency change instruction 21. The specific control method will be described later.

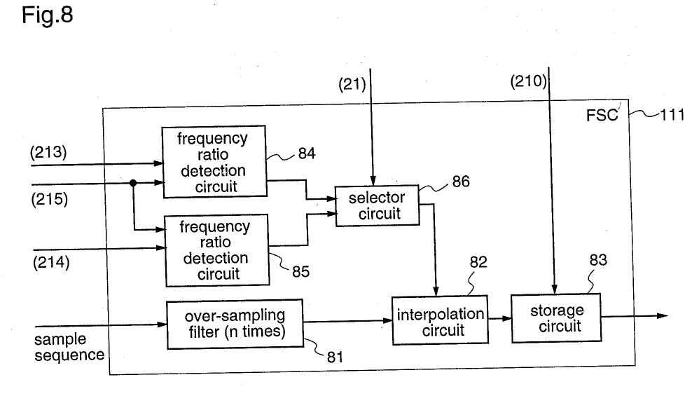

Next, the specific construction of the FSC 111 will be described. FIG. 8 is a block diagram illustrating a configuration example of the FSC 111. The FSC 111 includes an over-sampling filter 81 for over-sampling the input sample sequence, i.e., for integer(n)-multiplying the sampling frequency of the input sample sequence, an interpolation circuit 82 for interpolating the sample sequence outputted from the over-sampling filter 81 to obtain sample values corresponding to temporal positions of the first word clock 210, and a first-in first-out (FIFO) type storage circuit 83 for storing the output of the interpolation circuit 82 and outputting the same on the basis of the cycle of the first word clock 210, and the FSC 111 performs frequency conversion to the input sample sequence so as to make the sampling frequency thereof equal to the frequency of the first word clock 210.

The interpolation circuit 82 performs linear interpolation to the sample sequence using the sampling frequency ratio between the input sample sequence and the output sample sequence to enhance the accuracy of the sample values in the sample sequence having the converted sampling frequency. The FSC 111 includes a frequency detector for obtaining a frequency ratio between the input sample sequence and the output sample sequence. In this first embodiment, since the frequency of the first word clock 210 is switched between the two kinds of frequencies according to the reception frequency of the radio receiver 13, the FSC 111 includes two types of frequency ratio detection circuits, i.e., frequency ratio detection circuits 84 and 85. The frequency ratio detection circuit 84 detects a frequency ratio between the clock 213 outputted from the 128 frequency divider 24 in the clock generator 110 and the bit clock 215 synchronized with the input sample sequence. The frequency ratio detection circuit 85 detects a frequency ratio between the clock 214 outputted from the 144 frequency divider 25 in the clock generator 110 and the bit clock 215 synchronized with the input sample sequence. The bit clock 215 is supplied from the ADC 14. The selection circuit 86 selects either of the outputs from the frequency ratio detection circuits 84 and 85 in accordance with the output sampling frequency change instruction 21. Thereby, the frequency ratio to be used in the interpolation circuit 82 can be switched according to the frequency of the first word clock 210.

Hereinafter, the frequency ratio detection circuits 84 and 85 each for obtaining the sampling frequency ratio between the input and output sample sequences will be described in detail. In this first embodiment, the frequency ratio detection circuit 84 (85) frequency-divides the clock 213 (214) supplied from the clock generator 110 with a predetermined frequency division ratio (e.g., 8192), and measures the number of bit clocks 215 synchronized with the input sample sequence within one period of the frequency-divided clock, thereby to obtain an average value of the frequency ratio. For example, assuming that the frequency of the clock supplied from the clock generator 110 is 400 kHz and the frequency-division ratio thereof is 8192, updation of the frequency ratio data is carried out for about every 20 ms (8192÷400≈20).

Although the accuracy of the frequency ratio can be enhanced by increasing the frequency-division ratio of the clock, if the sampling frequency of the input sample sequence is deviated due to some factor, the frequency ratio detection is adversely affected by the deviation for a long time. In order to solve this problem, the frequency ratio detection circuits 84 and 85 are constituted as follows. That is, each frequency ratio detection circuit measures the number of bit clocks 215 for each 4096 frequency division of the clock supplied from the clock generator 110, and adds the measured continuous two numbers of clocks to use the sum as a frequency ratio to be obtained when 8192 frequency division is performed. Thus, the data are updated for each 4096 frequency division while ensuring the accuracy corresponding to 8192 frequency division, thereby reducing the influence of disturbance such as deviation of the sampling frequency of the input sample sequence.

In this first embodiment, the number of clocks is measured for each 4096 frequency division, and the sum of the measured data obtained in twice measurements is used as the frequency ratio. However, when the data updation cycle is sufficient to be 20 ms, it is also possible to obtain a frequency ratio having an accuracy corresponding to 16384 frequency division by measuring the number of clocks for each 8192 frequency division and adding the measured data obtained in twice measurements. Conversely, by reducing the frequency division ratio while increasing the number of measured data to be added, frequency comparison having a shorter updation cycle can be achieved with the same accuracy.

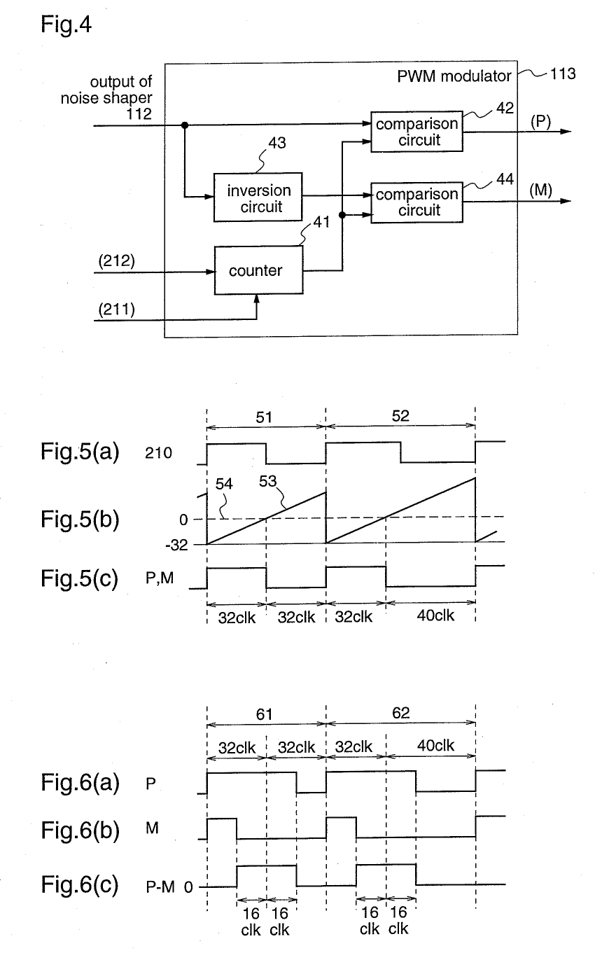

Next, the specific construction of the PWM modulator 113 will be described. FIG. 4 is a block diagram illustrating a configuration example of the PWM modulator 113. In FIG. 4, the PWM modulator 113 includes a counter 41 which is reset at rising edges of the second word clock 211 and performs one-by-one counting with a clock 212 (master clock) outputted from the clock generator 110, a comparison circuit 43 for comparing the output of the noise shaper 112 with the output of the counter 41, an inversion circuit 43 for inverting the polarity of the output of the noise shaper 112, and a comparison circuit 44 for comparing the output of the inversion circuit 43 with the output of the counter 41. The PWM modulator 113 outputs a positive-side pulse signal P from the comparison circuit 42, and a negative side pulse signal M from the comparison circuit 43.

Hereinafter, the operation of the pulse modulation circuit 17 constituted as described above will be described with reference to FIGS. 3 to 6. FIG. 3 is a diagram illustrating output signal waveforms from the major parts of the pulse conversion circuit 17. FIG. 3(a) shows the output sampling frequency change instruction issued from the system controller 12, 3(b) shows the first word clock 210 inputted to the FSC 111, 3(c) shows the second word clock 211 inputted to the noise shaper 112, 3(d) shows the positive-side pulse signal P outputted from the PWM modulator 113, 3(e) shows the negative-side pulse signal M outputted from the PWM modulator 113, and 3(f) shows a differential signal between the positive-side pulse signal P and the negative-side pulse signal M. In FIG. 3, for example, 128clk indicates a master clock 22 having a length equivalent to 128 periods. Further, to simplify the description, the output of the noise shaper 112 is assumed to be 0.

Initially, the operation of the clock generator 110 will be described. The clock generator 110 receives the master clock 22, and performs various kinds of frequency divisions to the same. For example, when a clock signal of 51.2 MHz is used as the master clock 22, the 128 frequency divider 24 outputs a clock signal of 400 kHz (51.2 MHz÷128≈400 kHz), and the 144 frequency divider 25 outputs a clock signal of about 356 kHz (51.2 MHz÷144≈356 kHz). Further, the 64 frequency divider 26 outputs a clock signal of 800 kHz, and the 72 frequency divider 27 outputs a clock signal of about 711 kHz. The selection circuits 28 and 29 select clock signals to be outputted as the word clocks 210 and 211 in accordance with the output sampling frequency change instruction 21 supplied from the system controller 12, respectively. The clock generator 110 selects the outputs of the 128 frequency divider 24 and the 64 frequency divider 26 when the output sampling frequency change instruction 21 is L level, and selects the outputs of the 144 frequency divider 25 and the 72 frequency divider 27 when the instruction 21 is H level.

When the system controller 12 sets the reception frequency of the radio receiver 13 in response to an instruction from the user, it changes the level of the output sampling frequency change instruction 21 according to the frequency to make the carrier frequency of the pulse signal outputted from the PMW modulator 113 apart from the reception frequency of the radio receiver 13. For example, when the master clock is 51.2 kHz and the reception frequency of the radio receiver 13 is 800 kHz, the output sampling frequency change instruction 21 is set at H level so that the output of the 144 frequency divider 25 is selected as the first word clock 210 while the output of the 72 frequency divider 27 is selected as the second word clock 211. The reason is as follows. When the master clock is 51.2 kHz, the frequency of the clock outputted from the 64 frequency divider 26 becomes 800 kHz (51.2 MHz÷64), and if the PMW modulator 113 converts the sample sequence into a pulse signal using this clock as the second word clock 211, the carrier frequency of the pulse signal overlaps with the reception frequency of the radio receiver 13, which causes radio reception interference. In contrast to this, since the frequency of the clock outputted from the 72 frequency divider 26 is about 711 kHz (51.2÷74), it does not overlap with the reception frequency of the radio receiver 13.

For the reason mentioned above, when the master clock is 51.2 MHz, the system controller 12 sets the output sampling frequency change instruction 21 at H level when the reception frequency of the radio receiver is close to a multiple of 800 kHz such as 800 kHz or 1600 kHz, while it sets the output sampling frequency change instruction 21 at L level when the reception frequency of the radio receiver 13 is close to a multiple of 711 kHz.

Hereinafter, the operation of the clock generator 110 will be described for the case where the output sampling frequency change instruction 21 is changed from L level to H level. When the output sampling frequency change instruction 21 is changed from L level to H level (FIG. 3(a)), the selection circuit 28 selects the clock (frequency of about 356 kHz) outputted from the 144 frequency divider 25 as the first word clock 210 (FIG. 3(b)), and in conjunction with this, the selection circuit 29 selects the clock outputted from the 72 frequency divider 27 as the second word clock 211 (FIG. 3(c)). At this time, the timings of outputting the clocks from the selection circuits 28 and 29 are controlled by the timing adjustment circuit 23.

Hereinafter, the specific operation of the timing adjustment circuit 23 will be described. The timing adjustment circuit 23 changes, while monitoring the outputs of the 128 frequency divider 24, the 144 frequency divider 25, the 64 frequency divider 26, and the 72 frequency divider 27, the outputs of the selection circuits 28 and 29 at the timing when the rising edges of all the outputs are aligned with each other. Since 64 frequency division and 72 frequency division are double of 128 frequency division and 144 frequency division, respectively, it is only necessary to consider the phases of 128 frequency division and 144 frequency division having relatively low frequencies by aligning the initial phases of the 64 frequency divider 26, the 72 frequency divider 27, the 128 frequency divider 24, and the 144 frequency divider 25. Since 9 periods of 128 frequency division=1152 clocks=8 periods of 144 frequency division, the rising edges of the outputs of the 128 frequency divider 24 and the 144 frequency divider 25 are aligned at every 9 periods with the output of the 128 frequency divider 24 being a basis. Since, at this time, the rising edges of the outputs of the 64 frequency divider 26 and the 72 frequency divider 27 are also aligned, the outputs of the selection circuits 28 and 29 are switched at this timing. Although the switching is performed delayed by 9 periods of 128 frequency division at maximum from when the output sampling frequency change instruction 21 has become H level, this delay is only 22.5 μsec (1÷400000×9=0.0000225) as an actual time, and such a small delay causes no problem in practical use. The above-mentioned operation of the timing adjustment circuit 23 enables the frequency switching without disordering the respective periods of and the relative phase relationship between the first word clocks 210 outputted to the FSC 111 and the second word clock 211 used by the noise shaper 112 and the PWM modulator 113. As the result, occurrence of abnormal noise at the switching can be avoided.

Next, the operation of the FSC 111 will be described. The FSC 111 converts the sampling frequency of the sample sequence outputted from the S/P 15 so as to be equal to the frequency of the first word clock 210. For example, when the master clock is 51.2 MHz and the output sampling frequency change instruction 21 is L level, since the frequency of the first word clock 210 is 400 kHz, the FSC 111 converts the sampling frequency of the sample sequence to 400 kHz. Initially, the FSC 111 integer-multiples (e.g., 1024 times) the sample sequence using the over-sampling filter 81. The over-sampled sample sequence is input to the interpolation circuit 82. The interpolation circuit 82 obtains sample values corresponding to temporal positions of the first word clock 210 by performing interpolation. That is, it linearly interpolates the sample sequence using the ratio of the sampling frequencies of the input sample sequence and the output sample sequence. When the sampling frequency change instruction 21 is L level, the interpolation circuit 82 interpolates the sample sequence using the frequency ratio between the clock 213 outputted from the 128 frequency divider 24 and the bit clock 215 of the sample sequence, which ratio is detected by the frequency ratio detection circuit 84, while when the sampling frequency change instruction 21 is H level, the interpolation circuit 82 interpolates the sample sequence using the frequency ratio between the clock 214 outputted from the 144 frequency divider 25 and the bit clock 215 of the sample sequence, which ratio is detected by the frequency ratio detection circuit 85. The interpolated sample sequence is stored in the storage circuit 83. The storage circuit 83 outputs the stored sample sequence by the FIFO method on the basis of the period of the first word clock 210.

Next, the operation of the noise shaper 112 will be described. The noise shaper 112 receives the sample sequence outputted from the FSC 111, and performs noise shaping after increasing the sampling frequency of the sample sequence to double by a previous-value holding process based on the second word clock 211 outputted from the clock generator 110. The noise shaper 112 performs noise shaping with the sampling frequency of 800 kHz when the output sampling frequency change instruction 21 is L level, and with the sampling frequency of about 711 kHz when the output sampling frequency change instruction 21 is H level.

Next, the operation of the PWM modulator 113 will be described. The PWM modulator 113 receives the output of the noise shaper 112, and converts the same into pulse signals P and M. The PWM modulator 113 makes the carrier frequencies of the pulse signals equal to the frequency of the second word clock 211. In the case where the master clock is 51.2 kHz, the PWM modulator 113 outputs pulse signals having a carrier frequency of 800 kHz when the output sampling frequency change instruction 21 is L level, while outputs pulse signals having a carrier frequency of about 711 kHz when the output sampling frequency change instruction 21 is H level. Since the period of the second word clock 211 changes from 64 clocks to 72 clocks when the output sampling frequency change instruction 21 changes from L level to H level, the PWM modulator 113 increases the periods of the falling edges of the pulse signals P and M each by 8 clocks to change the carrier frequencies thereof (FIGS. 3(d) and 3(e)).

Hereinafter, the specific operation of the PWM modulator 113 to realize the change in the carrier frequency will be described with reference to FIG. 5. FIG. 5 is a diagram for explaining the operation of the PWM modulator 113. FIG. 5(a) is a waveform diagram illustrating the first word clock 210, 5(b) is a schematic diagram illustrating the result of comparison between the output of the noise shaper 112 and the output of the counter 41 when the output of the noise shaper 112 is 0, and 5(c) is a waveform diagram illustrating the pulse signal P outputted from the comparison circuit 42 and the pulse signal M outputted from the comparison circuit 44. Further, period 51 is a period in which the output sampling frequency change instruction 21 is L level, and period 52 is a period in which the output sampling frequency change instruction 21 is H level.

In the case where the output sampling frequency change instruction 21 is L level, since the period of the second word clock 211 is 64 clocks, the counter 41 resets the output 53 to −32 at the rising edge of the second word clock 211. The comparison circuit 42 compares the output 53 of the counter 41 and the output 54 of the noise shaper 112, and outputs H level when the output 53 of the counter 41 is smaller than the output 54 of the noise shaper 112. When the clock 212 is counted by 32 clocks, the output 53 of the counter 41 becomes 0, and the output of the comparison circuit 42 becomes L level. After more 32 clocks are counted, the second word clock 211 rises, and the output of the comparison circuit 42 becomes H level again. Thus, the carrier frequency of the pulse signal P becomes 800 kHz.

In the case where the output sampling frequency change instruction 21 is H level, when the rising edge of the second word clock 211 is input to the counter 41, the counter 41 resets the output 53 to −32. When the clock 212 is input by 32 clocks to the counter 41, the output 53 of the counter 41 becomes 0, and the output of the comparison circuit 42 becomes L level. The operation up to here is identical to that in the case where the output sampling frequency change instruction is L level. However, when the output sampling frequency change instruction 21 is H level, since the period of the second word clock 211 is 72 clocks, the output of the comparison circuit 42 is L level during a period of 40 clocks until the next rising edge is inputted to the counter 41. Accordingly, when the output sampling frequency change instruction 21 becomes H level, the carrier frequency of the pulse signal P outputted from the PWM modulator 113 becomes about 711 kHz (51.2 MHz÷72).

Since the output of the noise shaper 112 is “0”, the output of the comparison circuit 44 which compares the output of the inversion circuit 43 and the output of the counter 41 becomes equal to the output of the comparison circuit 42.

By the above-described operation, the pulse signals having the carrier frequency of 800 kHz are outputted from the comparison circuits 42 and 44 when the output sampling frequency change instruction 21 is L level, while the pulse signals having the carrier frequency of about 711 kHz are outputted when the output sampling frequency change instruction 21 is H level. In this way, according to the reception frequency of the radio receiver 13, the carrier frequencies of the pulse signals are switched so as to be separated from the reception frequency of the radio receiver 13, thereby avoiding radio reception interference.

Next, the operation of the PWM modulator 113 when the output of the noise shaper 112 is other than 0 will be described with reference to FIG. 6. FIG. 6 shows the waveforms of the pulse signals P and M which are obtained when the output of the noise shaper 112 is +16, and the waveform of a differential signal between the pulse signal P and the pulse signal M. To be specific, FIG. 6(a) shows the waveform of the positive-side pulse signal P outputted from the PWM modulator 113, 6(b) shows the waveform of the negative-side pulse signal M outputted from the PWM modulator 113, and 6(c) shows a differential signal between the positive-side pulse signal P and the negative-side pulse signal M. Further, 61 indicates a period in which the output sampling frequency change instruction 21 is L level, and 62 indicates a period in which the output sampling frequency change instruction 21 is H level.

In the period 61 where the output sampling frequency change instruction 21 is L level, the counter 41 resets its output to −32 at the rising edge of the second word clock 211. The comparison circuit 42 compares the output of the counter 41 and the output (+16) of the noise shaper 112, and outputs H level when the output of the counter 41 is smaller than the output of the noise shaper 112, while outputs L level when it is larger than the output of the noise shaper 112. Accordingly, the positive-side pulse signal P rises after 16 clocks counting from the 32nd clock which is the center of the period 61. On the other hand, the comparison circuit 44 compares the output of the counter 41 and the output (−16) of the inversion circuit 43, and outputs H level when the output of the counter 41 is larger than the output of the inversion circuit 43, and L level when it is smaller than the output of the inversion circuit 43. Accordingly, the negative-side pulse signal M falls before 16 clocks counting from the 32nd clock which is the center of the period 61.

In the period 62 where the output sampling frequency change instruction 21 is H level, the output of the comparison circuit 42 becomes L level when the master clock 212 is counted by 48 clocks, and the output of the comparison circuit 44 becomes L level when the master clock 212 is counted by 16 clocks. The operation up to here is identical to that in the period 61. When the output sampling frequency change instruction 21 is H level, since the period 62 of the second word clock 211 is 72 clocks, the comparison circuits 42 and 44 output L level each by 8 clocks longer than the period 61.

By the above-described operation, the pulse signals having the carrier frequency of 800 kHz are outputted from the comparison circuits 42 and 44 when the output sampling frequency change instruction 21 is L level, while the pulse signals having the carrier frequency of about 711 kHz are outputted when the output sampling frequency change instruction 21 is H level.

As described above, the PMW modulator 113 is operated so as not to change the positions of the falling edges of the pulse signals P and M from the beginnings of the cycles, i.e., the beginning of the periods 61 and 62, between the period 61 where the output sampling frequency change instruction 21 is L level and the period 62 where it is H level, regardless of the output value from the noise shaper. As the result, when the output of the noise shaper 112 is +16, the differential signal between the pulse signals P and M becomes a positive polarity pulse having a width of 32 clocks with the 32nd clock in the center. Also in the period 62 wherein the output sampling frequency change instruction 21 is H level, the positions of the falling edges of the positive-side pulse signal P and the negative-side pulse signal M are not changed, and the center position of the differential signal is also not changed from the 32nd clock counted from the beginning of the period (FIG. 6(c)). The differential signal becomes a positive polarity pulse having a width of 32 clocks as in the case where the output sampling frequency change instruction 21 is L level. Although the center position of the differential signal deviates from the center of the carrier period (36th clock from the beginning of the period) by an amount equivalent to the extension of the carrier period (an inverse of the carrier frequency) from 64 clocks to 72 clocks, this deviation is constant regardless of the value outputted from the noise shaper 112.

Thus, the audio output from the speaker 20 is stabilized by making the rising edge width of the differential signal between the pulse signals P and M constant.

Further, the PWM modulator 113 is operated so as not to change the positions of the respective falling-edges of the positive-side pulse signal P and the negative-side pulse signal M from the beginnings of the period 61 and the period 62, thereby to change the carrier frequency without changing the center of the differential signal between the pulse signal P and the pulse signal M. Therefore, the PWM modulator 113 can change the carrier frequency with a simple circuit structure comprising a combination of simple circuits such as a comparison circuit, an inversion circuit, and a counter.

As described above, in the electronic device according to the first embodiment, the system controller 12 changes the level of the output sampling frequency change instruction 21 according to the reception frequency of the radio receiver 13, and the clock generator 110 in the pulse conversion circuit 17 changes, according to this instruction, the sampling frequencies of the clocks to be output to the FSC 111, the noise shaper 112, and the PWM modulator 113. Thereby, occurrence of radio reception interference which may be caused by the pulse signal can be avoided by that the carrier frequency of the pulse signal applied to the speaker 20 is changed according to the reception frequency of the radio receiver.

### Embodiment 2

In the pulse conversion circuit of the electronic device according to the first embodiment, the positions of the rising edges of the positive-side pulse signal P and the negative-side pulse signal M which are outputted from the PWM converter 113 are not changed when changing the carrier frequencies of the pulse signals, thereby to keep the pulse width of the differential signal between the pulse signals P and M constant. In this construction, however, the energy of the pulse signal per unit time changes with the change in the carrier frequency. This means that the amplitude of the acoustic signal outputted from the speaker 20 changes. A pulse conversion circuit of an electronic device according to a second embodiment of the present invention is constituted to avoid the change in the amplitude of the acoustic signal with the change in the carrier frequency.

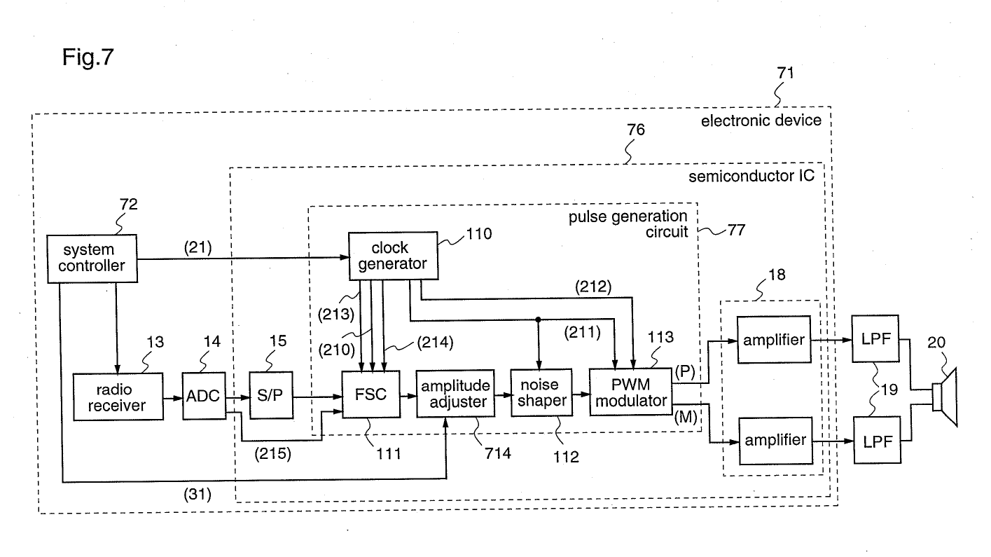

FIG. 7 is a block diagram illustrating configuration examples of an electronic device according to the second embodiment, a semiconductor integrated circuit mounted on the electronic device, and a pulse conversion circuit integrated in the semiconductor integrated circuit.

The pulse conversion circuit 77 in the electronic device 71 according to the second embodiment includes an amplitude adjustment unit 714 for changing the size of the sample sequence outputted from the FSC 111 according to an amplitude adjustment instruction 31 corresponding to the reception frequency of the radio receiver 13, which instruction is outputted from the system controller 72. The amplitude adjustment unit 714 changes the sample values in the sample sequence according to the amplitude adjustment instruction 31 to adjust the amplitude of the acoustic signal. For example, the amplitude adjustment unit 714 comprises a multiplier. In this case, the amplitude adjustment unit 714 changes the sample values in the sample sequence by changing the multiplier coefficient for the sample sequence.

Hereinafter, the operation of the amplitude adjustment unit 714 in the pulse conversion circuit 77 in the electronic device 71 according to the second embodiment will be described for the case where the output of the noise shaper 112 is +16. Since the other operations are identical to those described in the first embodiment, repeated description is not necessary.

The PWM modulator 113, using the method described in the first embodiment, compares the output of the noise shaper 112 with the count result of the clock 212 to output the positive-side pulse signal P, and compares the inversion result of the output of the noise shaper 112 with the count result of the clock 212 to output the negative-side pulse signal M. When the output of the noise shaper 112 is +16, a differential signal between the pulse signal P and the pulse signal M becomes a positive polarity signal having a pulse width of 32 clocks irrespective of the level of the output sampling frequency change instruction 21. However, since the carrier period is 72 clocks when the output sampling frequency change instruction 21 is H level while it is 64 clocks when the instruction 21 is L level, if the output sampling frequency change instruction 21 is changed from L level to H level, the amplitude of the acoustic signal is reduced by about 1 dB (20 log((32÷72)÷(32÷64))≈−1.02).

Accordingly, in this second embodiment, the system controller 72 changes the amplitude adjustment instruction 31 from L level to H level when changing the output sampling frequency change instruction 21 from L level to H level. In response to that the amplitude adjustment instruction 31 has become H level, the amplitude adjustment unit 714 increases the sample values in the sample sequence outputted from the FSC 111 by 1 dB to increase the amplitude of the acoustic signal.

As described above, in the electronic device of this second embodiment, the amplitude of the acoustic signal is adjusted by the amplitude adjustment unit 714 accompanying with that the carrier frequency of the pulse signal is changed according to the reception frequency of the radio receiver 13. Thereby, the electronic device of this second embodiment can suppress variations in the sound volume which may be caused by the change in the carrier frequency.

While in this second embodiment the amplitude adjustment unit 714 is disposed in the subsequent stage of the FSC 111, it may be disposed in the previous stage of the FSC 111. When the FSC 111 is constituted so as to convert input sample sequences having various sampling frequencies into a constant sampling frequency, the amplitude adjustment unit, which is disposed in the subsequent stage of the FSC 111, can perform the same amplitude adjusting process to any input. However, since the FSC 111 performs the process of increasing the sampling frequency, the amplitude adjustment unit 714 requires a higher operation frequency relative to the case where it is disposed in the previous stage of the FSC 111.

### Embodiment 3

While in the first embodiment the electronic device which avoids the radio reception interference which may be caused by the pulse signal has been described, there is an operation clock of a signal processing circuit in a semiconductor integrated circuit as another cause of reception interference. An electronic device according to a third embodiment of the present invention includes a semiconductor integrated circuit which avoids radio reception interference which may be caused by an internal operation clock.

Since the internal operation clock of the semiconductor integrated circuit is MHz order, this third embodiment is directed to solving reception interference to the band region of FM (Frequency Modulation) radio or television broadcasting.

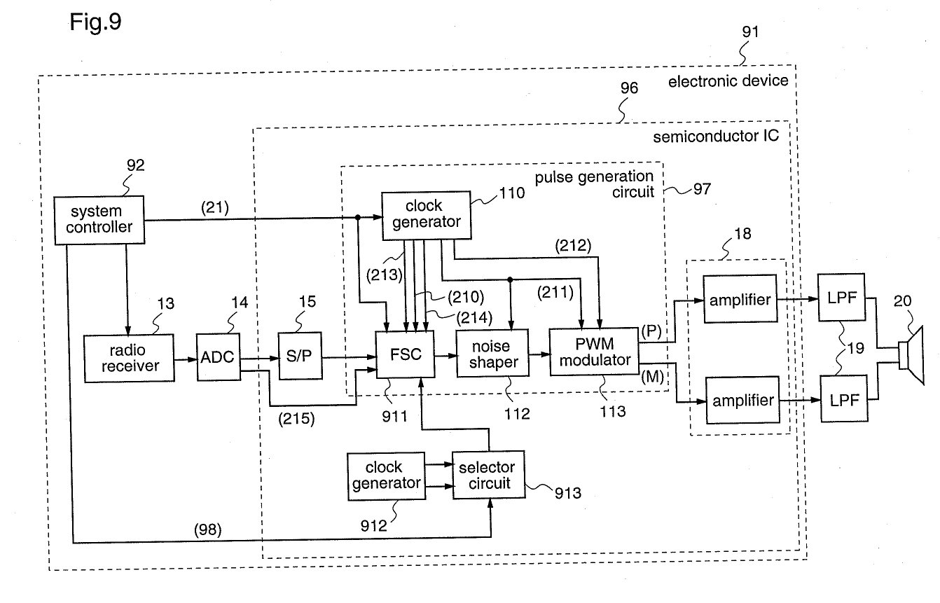

FIG. 9 is a block diagram illustrating a configuration example of an electronic device according to the third embodiment. In FIG. 9, a semiconductor integrated circuit 96 includes a clock generator 912 which generates operation clocks for a signal processing circuit, and a selector 913 which selects an operation clock for the signal processing circuit in accordance with an instruction from a system controller 92. The clock generator 912 may be constituted by plural crystal oscillators which generate clocks of required frequencies, or it may be constituted by a crystal oscillator and a PLL (Phase Locked Loop) circuit which selectively outputs a clock of a required frequency in accordance with a clock oscillated by the crystal oscillator. Alternatively, it may be constituted by combining frequency dividers with a crystal oscillator and a PLL.

This third embodiment will be described for the case of switching the operation clock for the over-sampling filter, the interpolation circuit, and the storage circuit which are signal processing circuits in the FSC 911 in the pulse conversion circuit 97. Since the over-sampling filter, the interpolation circuit, and the storage circuit in the FSC 911 have constant data throughputs (number of clocks), the outputs thereof are not affected by the switching of the operation clock.

The frequency of the clock signal to be generated by the clock generator 912 is determined according to the clock frequency which is required for the signal processing by the signal processing circuit whose operation clock should be switched. For example, assuming that the over-sampling filter or the interpolation circuit included in the FSC 911 processes 400 clocks for one input sample sequence and the sampling frequency is 192 kHz, the clock frequency required for this process is higher than 76.8 MHz (400×192000=76800000). Accordingly, in the semiconductor integrated circuit 96 shown in FIG. 9, the clock generator 912 generates clocks of 80 MHz and 88 MHz, and the selector 913 selects either of the clocks to operate the circuit in the FSC 911.

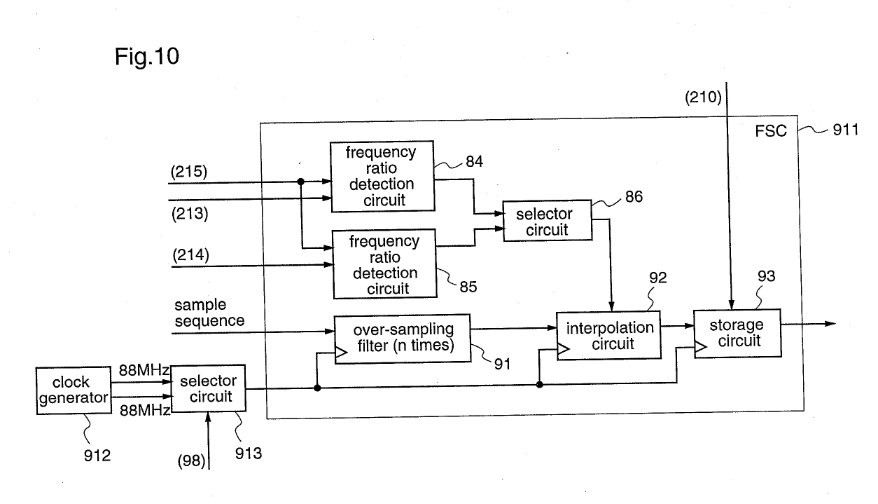

FIG. 10 is a block diagram illustrating a configuration example of the FSC 911. The FSC 911 receives the clock from the selector 913 to use the same as an operation clock for the over-sampling filter 91, the interpolation circuit 92, and the storage circuit 93.

The operation of the electronic device according to the third embodiment which is constituted as described above will be described. Hereinafter, only switching of the operation clock for the over-sampling FIG. 91, the interpolation circuit 92, and the storage circuit 93 will be described. Since the other operations are identical to those of the first embodiment, repeated description is not necessary.

When the system controller 12 controls the radio receiver 13 to receive radio broadcasting of a frequency around 80 MHz, it controls the selector 913 to select the clock of 88 MHz by the operation clock switching instruction 98. On the other hand, when the system controller 12 controls the radio receiver 13 to receive radio broadcasting of a frequency which is sufficiently apart from 80 MHz, it controls the selector 913 to select the clock of 80 MHz by the operation clock switching instruction 98. Since the signal throughputs (number of clocks) of the over-sampling filter 91, the interpolation circuit 92, and the storage circuit 93 are constant, these circuits complete their processings earlier with the operation clock of 88 MHz than with the operation clock of 80 MHz, and thereby the time for waiting the next sample input increases. However, since these circuits have the constant signal throughputs, the respective outputs thereof are not changed due to the switching of the operation clock.

As described above, the electronic device of this third embodiment includes the clock generator 912 for generating plural clocks of different frequencies and the selector 913 for selecting the operation clock to be outputted to the signal processing circuit in the semiconductor integrated circuit among the clocks generated by the clock generator 912, in the semiconductor integrated circuit 96, and switches the operation clock to be outputted to the signal processing circuit in the semiconductor integrated circuit 96 according to the reception frequency of the radio receiver 13. Thereby, the electronic device of this third embodiment can avoid occurrence of radio reception interference which may be caused by the internal operation clock in the semiconductor integrated circuit 96.

While in this third embodiment the operation clock for the over-sampling filter 91, the interpolation circuit 92, and the storage circuit 93 in the FSC 911 is switched according to the reception frequency of the radio receiver 13, the present invention is not restricted thereto. If there is a signal processing circuit whose output is not influenced even when its signal processing speed is changed by changing its operation clock, the operation clock of the signal processing circuit may be changed according to the reception frequency of the radio receiver 13 in like manner as that for the over-sampling filter 91, the interpolation circuit 92, and the storage circuit 93.

Further, while in this third embodiment the semiconductor integrated circuit 96 generates two kinds of internal operation clocks, the present invention is not restricted thereto. The semiconductor integrated circuit of the present invention may generate more than two kinds of internal operation clocks.

### Embodiment 4

An electronic device according to a fourth embodiment of the present invention removes noise in the acoustic signal, which noise varies for each operation mode, with considering the operation mode of the radio receiver, when converting the sampling frequency of the acoustic signal received by the radio receiver. The radio receiver generally has operation modes such as an AM (Amplitude Modulation) radio reception mode and an FM radio reception (also including audio of television) mode. In these operation modes, the transmittable acoustic bands are predetermined. In this fourth embodiment, in view of this point, the FSC in the pulse conversion circuit performs band control to the input sample sequence.

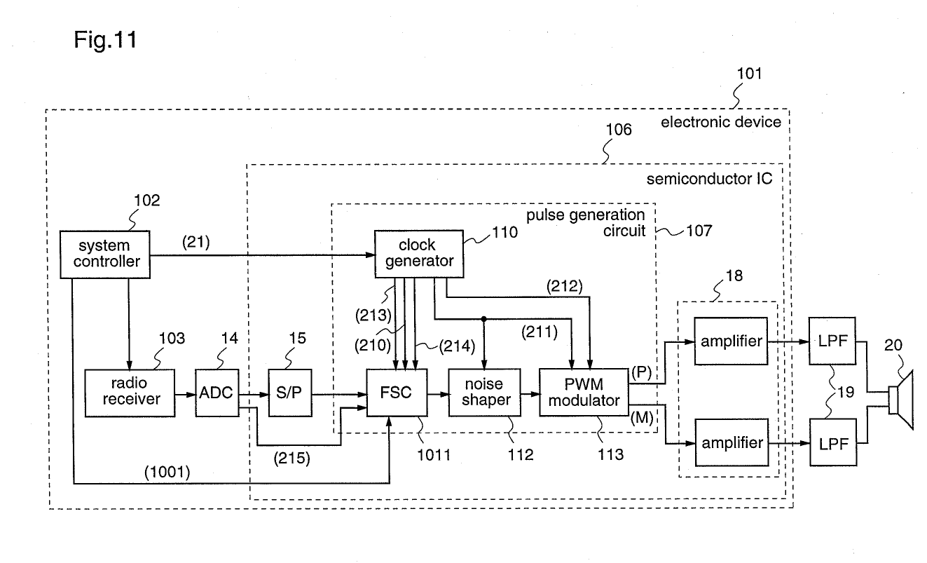

FIG. 11 is a block diagram illustrating a configuration example of the electronic device according to the fourth embodiment. The electronic device 101 includes a radio receiver 103 having plural operation modes, and a system controller 102 for designating an operation mode of the radio receiver 103 according to the reception frequency of the radio receiver 103. The system controller 102 outputs a band setting instruction 1001 in conjunction with the designation of the operation mode. This band setting instruction 1001 is input to the FSC 1011 in the pulse conversion circuit 107, and the FSC 1011 switches the band restriction operation for the input sample sequence according to the band setting instruction 1001.

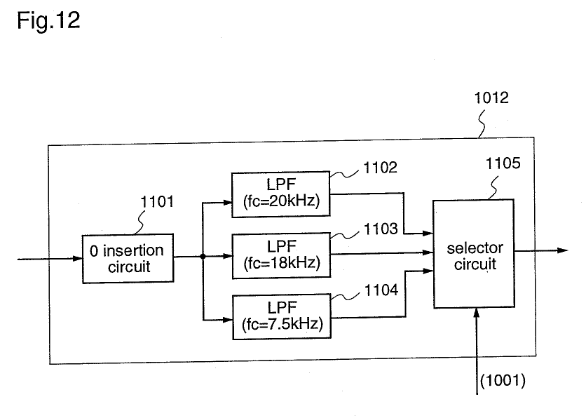

FIG. 12 is a block diagram illustrating a configuration example of the over-sampling filter 1012 included in the FSC 1011. The over-sampling filter 1012 includes a 0 insertion circuit 1101 for inserting 0 data between the respective samples in the inputted sample sequence to increase the sampling frequency, low-pass filters (LPFs) 1102 to 1104 for removing high-frequency components in the output of the 0 insertion circuit 1101, and a selector circuit 1105 for selecting one of the outputs of the LPFs 1102 to 1104 in accordance with the band setting instruction 1001. Since the LPFs are used in the over-sampling filter, noise components in the acoustic signal can be removed without adding new filters, by using these LPFs for band restriction.

Hereinafter, the operation of the electronic device 101 according to the fourth embodiment will be described. The description will be given of only the operation of performing band restriction to the input sample sequence by the FSC 1011 according to the operation mode of the radio receiver 103. Since the other operations are identical to those of the electronic device 11 according to the first embodiment, repeated description is not necessary.

When the user instructs reception of FM broadcasting, the system controller 102 sets the radio receiver 103 in the operation mode for receiving the FM broadcasting, and instructs the reception frequency. In accordance with this operation, the system controller 102 outputs a band setting instruction 1001 which instructs the selection circuit 1105 to select the output of the LPF 1103. Since the cutoff frequency of the LPF 1103 is 18 kHz, signal components exceeding 18 kHz are removed. Since the signal band of the FM broadcasting is 20 Hz to 18 kHz, noise components exceeding 18 kHz are removed. The selector circuit 1105 outputs the output of the LPF 1103 to the subsequent-stage interpolation circuit in accordance with the band setting instruction 1001.

When the user instructs reception of AM broadcasting, the system controller 102 outputs a band setting instruction 1001 which instructs the selection circuit 1105 to select the output of the LPF 1104. Since the cutoff frequency of the LPF 1104 is 7.5 kHz, signal components exceeding 7.5 kHz are removed. Since the maximum frequency of the AM broadcasting is 7.5 kHz, noise components exceeding 7.5 kHz are removed.

For example, when reproducing a sample sequence of an acoustic signal having a sampling frequency of 44.1 kHz which is recorded on a compact disc (CD), the system controller 102 outputs a band setting instruction 1001 which instructs the selector circuit 1105 to select the output of the LPF 1102. In this case, since the signal components exceeding the half of the sampling frequency, i.e., about 22 kHz, become noise components, it is possible to remove the noise without deteriorating the inputted acoustic signal, by using the LPF 1102 having the cutoff frequency of 20 kHz.

As described above, according to the electronic device of this fourth embodiment, the pass band of the over-sampling filter in the FSC 1011 is changed according to the operation mode of the radio receiver 103, and thereby the noise components in the acoustic signal which vary for each operation mode are removed. Thus, optimum audio can be outputted in each operation mode.

While in this fourth embodiment three kinds of LPFs are provided and the respective cutoff frequencies thereof are set at 20 kHz, 18 kHz, and 7.5 kHz, the cutoff frequencies are not restricted thereto. The values of the cutoff frequencies may be varied according the operation mode of the radio receiver.

Further, while in this fourth embodiment the pass band of the over-sampling filter in the FSC in the electronic device according to the first embodiment is change, the pass band of the over-sampling filter in the FSC according to the second or third embodiment may be changed.

While in the first to fourth embodiments the system controller, the radio receiver, and the ADC are not integrated on the semiconductor integrated circuit on which the pulse conversion circuit is integrated, all or some of these components may be integrated on the semiconductor integrated circuit.

Further, while in the first to fourth embodiment an input bit clock is used as a signal indicating the sampling frequency of the input sample sequence, a word clock or a signal obtained by multiplying a word clock may be used.

Further, while in the first to fourth embodiments two kinds of word clocks and two kinds of carrier frequencies are used, three or more kinds of frequencies may be used so long as the frequencies can avoid radio reception interference. When using three or more kinds of frequencies, the sampling frequency change instruction 21 is made of a signal comprising plural bits, thereby enabling switching of the word clock and the carrier frequency according to the reception frequency of the radio receiver.

Further, while in the first to fourth embodiments the amplifier 18 is integrated on the semiconductor integrated circuit, the amplifier may be isolated to be constituted by a semiconductor integrated circuit other than the pulse conversion circuit, for the purpose of increasing the output current to the speaker 20.

Further, while in the first to fourth embodiments the pulse conversion circuit is integrated on the semiconductor integrated circuit, there is no restriction on the method of realizing a semiconductor integrated circuit of the present invention, and it may be realized by a special circuit or a general-purpose processor. Alternatively, a semiconductor integrated circuit may be realized by utilizing a FPGA (Field Programmable Gate Array) which can be programmed after the semiconductor manufacturing process is completed, or a reconfigurable processor which can reconfigure connections and settings for circuit cells in the semiconductor integrated circuit.

Further, if a technology for circuit integration which is substitutable for a semiconductor integrated circuit is discovered in the future by a progress in semiconductor technology or another technology which derives from the semiconductor technology, it is of course possible to perform integration of function blocks using the technology. Adaptation of bio technology or the like is possible.

### APPLICABILITY IN INDUSTRY

Since the pulse conversion circuit, the semiconductor integrated circuit, and the electronic device according to the present invention are constituted so as to switch the carrier frequency of the pulse signal according to the reception frequency of the radio receiver, these are suitable for audio equipment including a radio receiver and a digital amplifier which converts an acoustic signal into a pulse signal to drive a speaker with the pulse signal.

1-17. (canceled)

18. An electronic device comprising:
a radio receiver for receiving radio broadcasting;
a controller for outputting an output sampling frequency change instruction corresponding to a reception frequency of the radio receiver;
a sampling frequency converter for converting a first sample sequence that is obtained by sampling an acoustic signal received by the radio receiver into a second sample sequence of a second sampling frequency according to the output sampling frequency change instruction outputted from the controller;
a noise shaper for receiving the second sample sequence as an input, and performing noise shaping to the second sample sequence with a third sampling frequency which is a multiple of the second sampling frequency; and
a pulse modulator for modulating a signal outputted from the noise shaper into a PWM signal using the third sampling frequency;
wherein said controller detects that the reception frequency of the radio receiver is equal to or close to a carrier frequency of the pulse modulator or a multiple of the carrier frequency, and thereby generates the output sampling frequency change instruction.

19. A semiconductor integrated circuit mounted on an electronic device as defined in claim 18, comprising;
a sampling frequency converter for receiving the output sampling frequency change instruction corresponding to the reception frequency of the radio receiver, and converting a first sample sequence that is obtained by sampling an acoustic signal received by the radio receiver with a first sampling frequency into a second sample sequence of a second sampling frequency according to the output sampling frequency change instruction;
a noise shaper for receiving the second sample sequence as an input, and performing noise shaping to the second sample sequence with a third sampling frequency which is a multiple of the second sampling frequency; and
a pulse modulator for modulating a signal outputted from the noise shaper into a PWM signal using the third sampling frequency.

20. An electronic device as defined in claim 18 wherein
an amplitude adjustment unit for adjusting the amplitude of the acoustic signal by varying the sample values in the first sample sequence is provided in the previous stage of the sampling frequency converter,
said controller outputs, to the amplitude adjustment unit, an amplitude adjustment instruction corresponding to the reception frequency of the radio receiver, and
said amplitude adjustment unit varies the sample values in the first sample sequence in accordance with the amplitude adjustment instruction.

21. An electronic device as defined in claim 18 wherein
an amplitude adjustment unit for adjusting the amplitude of the acoustic signal by varying the sample values in the second sample sequence is provided in the subsequent stage of the sampling frequency converter,
said controller outputs, to the amplitude adjustment unit, an amplitude adjustment instruction corresponding to the reception frequency of the radio receiver, and
said amplitude adjustment unit varies the sample values in the second sample sequence in accordance with the amplitude adjustment instruction.

22. A semiconductor integrated circuit as defined in claim 19 wherein
an amplitude adjustment unit for adjusting the amplitude of the acoustic signal by varying the sample values in the first sample sequence is provided in the previous stage of the sampling frequency converter, and
said amplitude adjustment unit varies the sample values in the first sample sequence in accordance with an amplitude adjustment instruction corresponding to the reception frequency of the radio receiver, which instruction is outputted from the controller.

23. A semiconductor integrated circuit as defined in claim 19 wherein
an amplitude adjustment unit for adjusting the amplitude of the acoustic signal by varying the sample values in the second sample sequence is provided in the subsequent stage of the sampling frequency converter, and
said amplitude adjustment unit varies the sample values in the second sample sequence in accordance with an amplitude adjustment instruction corresponding to the reception frequency of the radio receiver, which instruction is outputted from the controller.

24. A semiconductor integrated circuit as defined in claim 19 including
a clock generator for generating plural clocks having different frequencies,
a selector for selecting one clock among the plural clocks generated by the clock generator in accordance with an operation clock switching instruction corresponding to the reception frequency of the radio receiver, which instruction is outputted from the controller, and
a signal processing unit which is operated with the clock outputted from the selector as an operation clock.
